(19) United States
(12) Patent Application Publication
(10) Pub. No.: US 2026/0040957 A1
(43) Pub. Date: Feb. 5, 2026

(54) METHOD OF FORMING PACKAGE STRUCTURE

(71) Applicant: Advanced Semiconductor Engineering, Inc., Kaohsiung (TW)

(72) Inventors: Chien-Fan CHEN, Kaohsiung (TW); Chia-Pin CHEN, Kaohsiung (TW); Wen Chung MA, Kaohsiung (TW); Chia Sheng TIEN, Kaohsiung (TW); Yen-Liang CHEN, Kaohsiung (TW)

(73) Assignee: Advanced Semiconductor Engineering, Inc., Kaohsiung (TW)

(21) Appl. No.: 18/789,615

(22) Filed: Jul. 30, 2024

(51) Int. Cl. H01L 21/48

(52) U.S. Cl. CPC H01L 21/4857

(57) ABSTRACT

A method of forming a package structure is provided. The method includes providing a carrier; forming a first conductive layer over the carrier; forming a barrier material layer over a surface the first conductive layer; melting the barrier material layer to allow the barrier material layer to flow from an upper side toward lateral sides of the first conductive layer to form a barrier layer over the first conductive layer and configured to reduce a lateral diffusion of the first conductive layer; and depositing a second conductive layer over the first conductive layer.

### BACKGROUND

### 1. Technical Field

The present disclosure relates generally to a method of forming a package structure.

### 2. Description of the Related Art

Currently, redistribution layers including copper wiring layers and dielectric layers that encapsulate the copper wiring layers may be used in bonding and electrically connecting various conductive features. However, as the pitches of the wiring layers are reduced, the distances between adjacent traces of the copper wiring layers may be reduced accordingly. As such, current leakage due to copper diffusion between adjacent copper traces may occur.

### SUMMARY

In one or more arrangements, a method of forming a package structure includes providing a carrier; forming a first conductive layer over the carrier; forming a barrier material layer over a surface the first conductive layer; melting the barrier material layer to allow the barrier material layer to flow from an upper side toward lateral sides of the first conductive layer to form a barrier layer over the first conductive layer and configured to reduce a lateral diffusion of the first conductive layer; and depositing a second conductive layer over the first conductive layer.

In one or more arrangements, a method of forming a package structure includes forming a first conductive layer over a carrier; forming a barrier material layer over an upper surface and sidewalls of the first conductive layer; and partially removing the barrier material layer to form a barrier layer on the sidewalls of the first conductive layer without contacting the upper surface of the first conductive layer.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A to FIG. 8B illustrate various stages of an exemplary method of forming a package structure in accordance with some arrangements of the present disclosure.

FIG. 9A illustrates one or more stages of an exemplary method of forming a package structure in accordance with some arrangements of the present disclosure.

FIG. 9B to FIG. 9C illustrate various stages of an exemplary method of forming a package structure in accordance with some arrangements of the present disclosure.

FIG. 10A to FIG. 16B illustrate various stages of an exemplary method of forming a package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

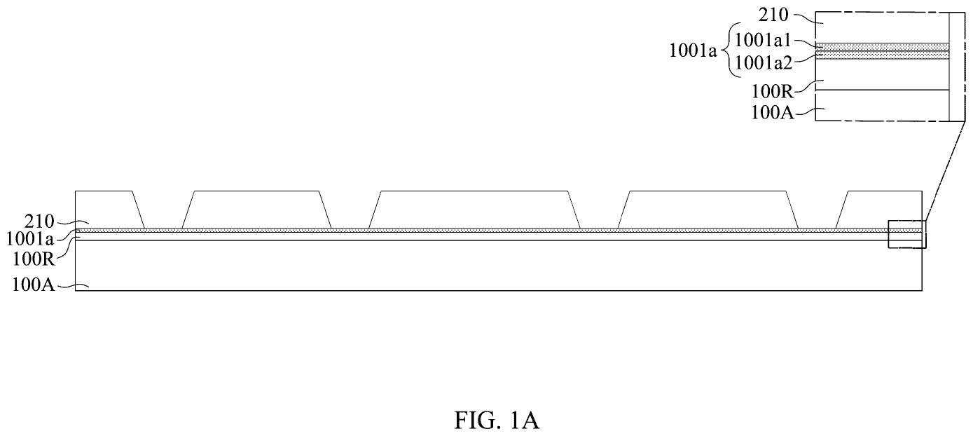

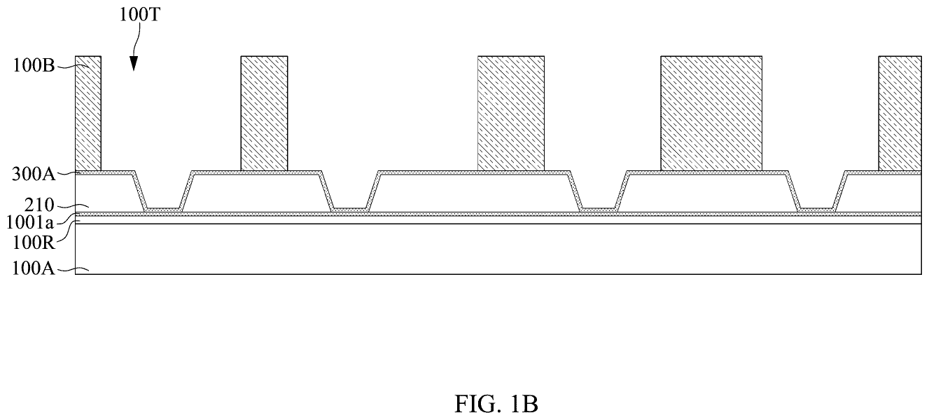

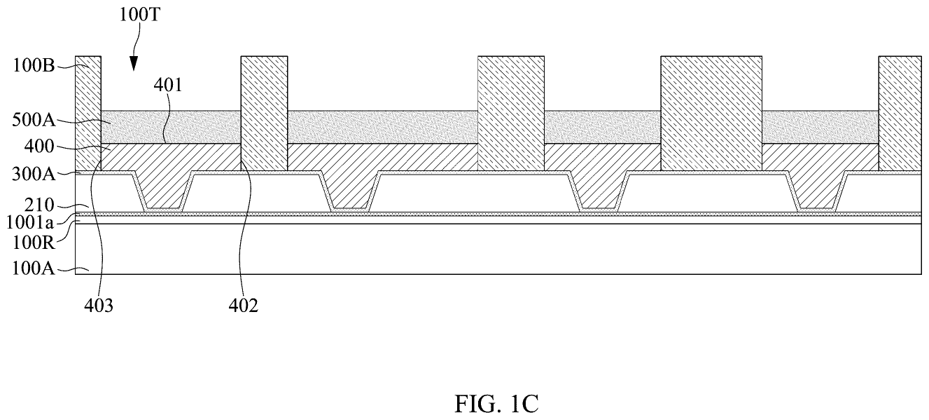

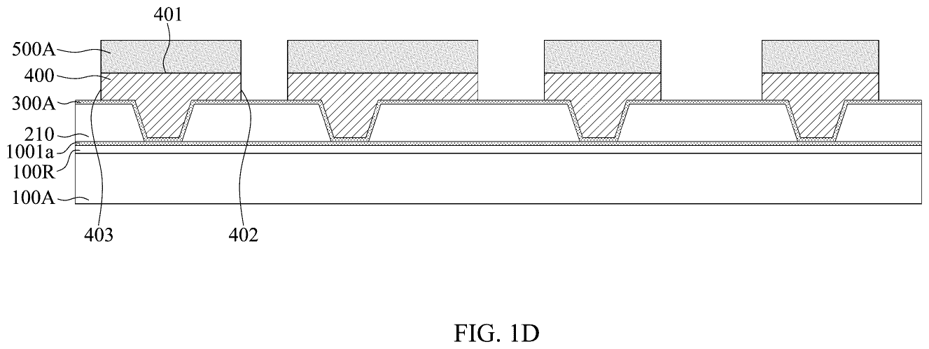

FIG. 1A to FIG. 8B illustrate various stages of an exemplary method of forming a package structure 1 in accordance with some arrangements of the present disclosure.

Referring to FIG. 1A, a carrier 100A may be provided, and a dielectric layer 210 may be disposed or formed over the carrier 100A. In some arrangements, a release film 100R is formed on the carrier 100A, and a seed layer 1001a is further formed on the release film 100R. The seed layer 1001a may include sub-layers 1001a1 and 1001a2, the sub-layer 1001a1 may be or include copper (Cu), and the sub-layer 1001a2 may be or include titanium (Ti). In some arrangements, the dielectric layer 210 has one or more openings or through holes that expose one or more portions of the carrier 100A (or the seed layer 1001a). The carrier 100A may be or include a glass carrier or a metal carrier (e.g., a stainless steel carrier), and the dielectric layer 210 may be or include one or more organic materials (e.g., phosphoric anhydride (PA), polyimide (PI), polybenzoxazole (PBO), epoxy, an epoxy-based material, or the like), one or more inorganic materials (e.g., silicon oxide (SiOₓ), silicon nitride (SiNₓ), tantalum oxide (TaOₓ), or the like) and/or one or more organic-inorganic composite materials (e.g., polypropylene (PP) including glass fibers), but the present disclosure is not limited thereto.

Referring to FIG. 1B, a sacrificial layer 100B having one or more through holes 100T may be disposed or formed over the carrier 100A. In some arrangements, a seed material layer 300A is formed over the carrier 100A and the dielectric layer 210, and then the sacrificial layer 100B is formed on the seed material layer 300A. The through holes 100T may expose the openings or through holes of the dielectric layer 210. In some arrangements, forming the seed material layer 300A over the carrier 100A is prior to forming the sacrificial layer 100B. The sacrificial layer 100B may be or include a photoresist, and the seed material layer 300A may include, for example, titanium (Ti), copper (Cu), nickel (Ni), another metal, or an alloy (such as a titanium-tungsten alloy (TiW)), but the disclosure is not limited thereto.

Referring to FIG. 1C, a conductive layer 400 may be disposed or formed over the carrier 100A, and the barrier material layer 500A may be disposed or formed over the carrier 100A. In some arrangements, the sacrificial layer 100B is disposed or formed prior to forming the conductive layer 400 and forming the barrier material layer 500A.

In some arrangements, the conductive layer 400 includes a plurality of trace portions formed on the dielectric layer 210. The trace portions may be separated or spaced apart from each other in a cross-sectional view perspective. The trace portions may be disposed or arranged on the dielectric layer 210 in a side-by-side manner.

In some arrangements, the barrier material layer 500A is formed over a top surface of an upper surface (e.g., a surface 401) of the conductive layer 400. In some arrangements, the conductive layer 400 and the barrier material layer 500A are formed in the through holes 100T. In some arrangements, the barrier material layer 500A is limited from contacting sidewalls (e.g., surfaces 402 and 403) of the conductive layer 400. The conductive layer 400 may have a thickness from about 2 μm to about 4 μm, e.g., about 3 μm. The barrier material layer 500A may have a thickness from about 2 μm to about 3 μm. In some arrangements, a melting point of the barrier material layer 500A is lower than a melting point of the conductive layer 400. The melting point of the barrier material layer 500A may be lower than 150° C., 120° C., 100° C., 80° C., 50° C., or 30° C. The conductive layer 400 may be or include a conductive material, e.g., gold (Au), silver (Ag), aluminum (Al), copper (Cu), or an alloy thereof. The barrier material layer 500A may be or include indium (In), gallium (Ga), or an alloy thereof. The conductive layer 400 and the barrier material 500A may be formed plating, deposition, or other suitable techniques.

In some arrangements, the barrier material layer 500A includes a plurality of portions (also referred to as “barrier portions”) each formed on a respective trace portion of the conductive layer 400. The portions of the barrier material layer 500A may be separated or spaced apart from each other in a cross-sectional view perspective.

Referring to FIG. 1D, the sacrificial layer 100B may be removed after forming the barrier material layer 500A. The sacrificial layer 100B may be removed by a stripping operation.

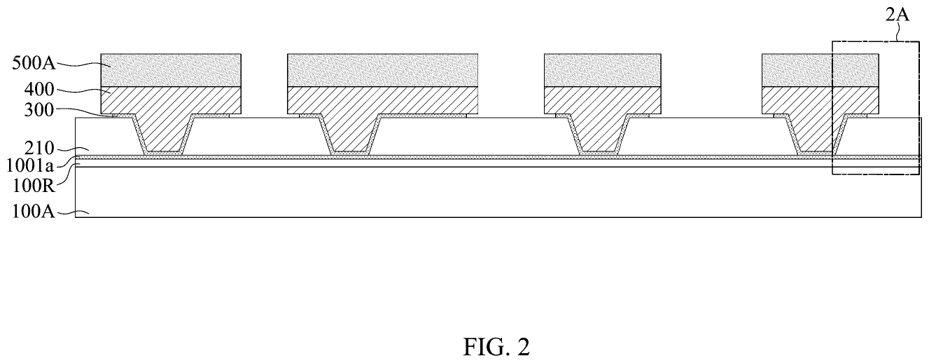

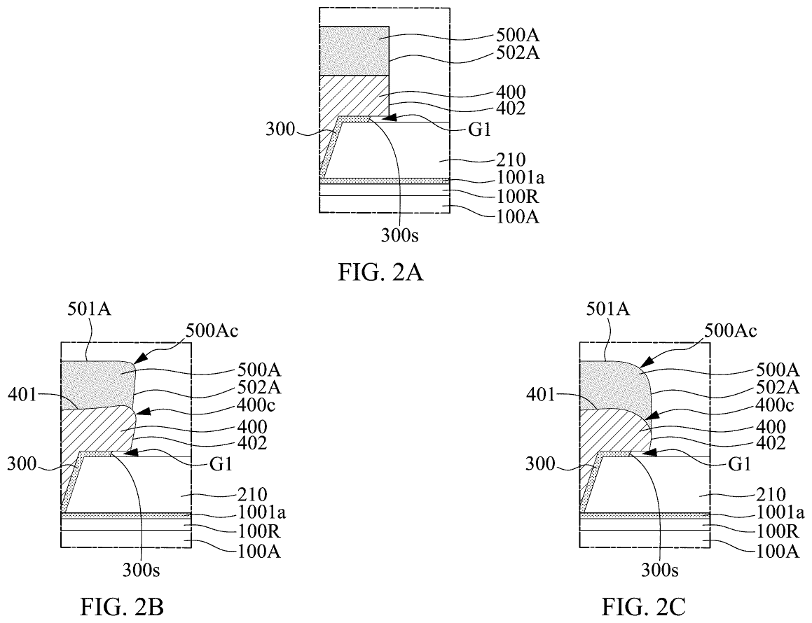

Referring to FIG. 2 and FIG. 2A, FIG. 2A shows a cross-sectional view of a portion 2A of the structure illustrated in FIG. 2 in accordance with some arrangements of the present disclosure. The seed material layer 300A may be partially removed after the sacrificial layer 100B is removed. In some arrangements, after the sacrificial layer 100B is removed, the seed material layer 300A is partially removed to form a seed layer 300 that is recessed with respect to the barrier material layer 500A. In some arrangements, the seed layer 300 may be formed to have a lateral side (e.g., a surface 300s), and the lateral side and the conductive layer 400 collectively define a gap G1. The seed material layer 300A may be partially removed by a wet etch operation that over-etches a portion of the seed material layer 300A to form an undercut (e.g., the gap G1) under an edge portion of the conductive layer 400. As shown in FIG. 2A, a lateral side (e.g., a surface 502A) of the barrier material layer 500A substantially aligns with a lateral side (e.g., the surface 402) of the conductive layer 400, and the surface 300s is recessed with respect to the surfaces 402 and 502A.

In some arrangements, referring to FIG. 2B, FIG. 2B shows a cross-sectional view of a portion 2A of the structure illustrated in FIG. 2 in accordance with some arrangements of the present disclosure. In some arrangements, an upper surface (e.g., a surface 501A) and a lateral side (e.g., the surface 502A) define a curved corner 500Ac of the barrier material layer 500A. In some arrangements, an upper surface (e.g., the surface 401) and a lateral side (e.g., the surface 402) define a curved corner 400c (also referred to as “a curved portion”) of the conductive layer 400. In some arrangements, the curved corner 400c is exposed by the barrier material layer 500A. In some arrangements, the surfaces 402 and 502A are inclined with respect to a normal line of an upper surface of the carrier 100A.

In some arrangements, referring to FIG. 2C, FIG. 2C shows a cross-sectional view of a portion 2A of the structure illustrated in FIG. 2 in accordance with some arrangements of the present disclosure. In some arrangements, the curved corner 400c is covered by the barrier material layer 500A.

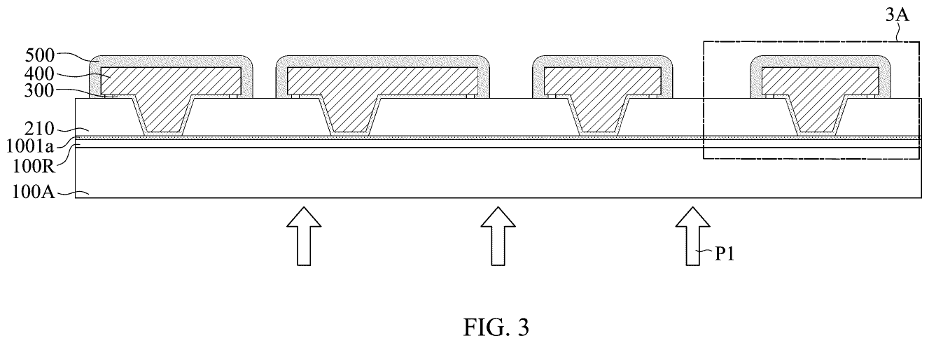

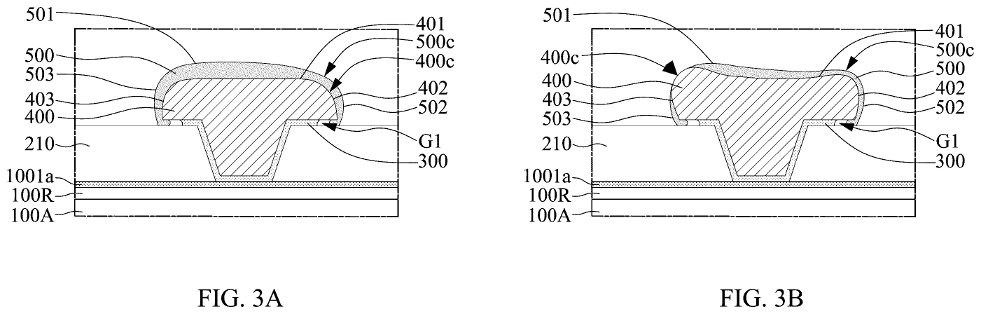

Referring to FIG. 3 and FIG. 3A, FIG. 3A shows a cross-sectional view of a portion 3A of the structure illustrated in FIG. 3 in accordance with some arrangements of the present disclosure. In some arrangements, a barrier layer 500 may be formed by melting the barrier material layer 500A, such that the as-formed barrier layer 500 extends over the sidewalls (e.g., the surfaces 402 and 403) of the conductive layer 400. In some arrangements, melting the barrier material layer 500A allows the barrier material layer 500A to flow from an upper side toward lateral sides of the conductive layer 400 to form the barrier layer 500 over the conductive layer 400 and configured to reduce a lateral diffusion of the conductive layer 400. In some arrangements, the thermal treatment P1 is performed at a temperature higher than a melting point of the barrier material layer 500A to allow the barrier material layer 500A to keep flowing over sidewalls (e.g., the surfaces 402 and 403) of the conductive layer 400. In some arrangements, the thermal treatment P1 includes heating the barrier material layer 500A until the barrier material layer 500A contacts the dielectric layer 210. In some arrangements, the thermal treatment P1 includes heating the barrier material layer 500A until the barrier material layer 500A flows below the conductive layer 400. A portion of the barrier layer 500 may further extend into the gap G1. In some arrangements, the molten barrier material layer 500A turns flowable to flow over and substantially cover the surfaces 402 and 403 of the conductive layer 400. The molten barrier material layer 500A may further flow into a portion of the gap G1. In some arrangements, when melting the barrier material layer 500A, it allows a portion of the barrier material layer 500A to extend into the gap G1. The molten barrier material layer 500A may be separated or spaced apart from the surface 300s of the seed layer 300 by a portion of the gap G1. In some arrangements, the barrier layer 500 includes a plurality of barrier portions each formed on a respective trace portion of the conductive layer 400. Each of the barrier portions may cover sidewalls of each of the trace portions of the conductive layer 400.

In some arrangements, melting the barrier material layer 500A includes performing a thermal treatment P1 on the barrier material layer 500A at a temperature lower than the melting point of the conductive layer 400. The thermal treatment P1 may be performed under a temperature lower than 150° C., 120° C., 100° C., 80° C., or 50° C. The thermal treatment P1 may be or include a hot baking operation, an inductively couple plasma (ICP) treatment, a reflow operation, or the like. In some arrangements, the thermal treatment P1 is performed in a direction from the carrier 100A toward the barrier material layer 500A. In some arrangements, in an initial stage of the thermal treatment P1 a lower portion of the barrier material layer 500A may be heated to melt when an upper portion of the barrier material layer 500A is not melted yet due to cohesion force of the barrier material layer 500A. In some arrangements, the thermal treatment P1 is performed until the upper portion of the barrier material layer 500A is heated to melt and overcome the cohesion force to overflow over the sidewalls (e.g., the surfaces 402 and 403) of the conductive layer 400. In some arrangements, after the entire barrier material layer 500A is heated and molted by the thermal treatment P1, the barrier material layer 500A overflows over the sidewalls (e.g., the surfaces 402 and 403) of the conductive layer 400, and thus the as-formed barrier layer 500 may have a thickness that is smaller than the thickness of the barrier material layer 500A, about 80% of the thickness of the barrier material layer 500A. In some arrangements, the thermal treatment P1 is performed on the barrier material layer 500A to form one or more convex curved surfaces (e.g., surfaces 501, 502, and 503) of the barrier material layer 500A. In some arrangements, one or more convex curved surfaces (e.g., surfaces 501, 502, and 503) of the barrier material layer 500A may be formed where melting the barrier material layer 500A. The molten barrier material layer 500A may tend to aggregate into a roughly spherical shape due to its cohesion, and thus the surfaces 501, 502, and 503 that are convex surfaces may be formed when melting the barrier material layer 500A.

In some arrangements, as shown in FIG. 3B, the barrier layer 500 includes curved corners 500c that connect the surfaces 501, 502, and 503 to form a convex curved surface facing away from the conductive layer 400. In some arrangements, the barrier layer 500 covers the surfaces 401, 402, and 403 and the curved corners 400c of the conductive layer 400.

In some arrangements, referring to FIG. 3B, FIG. 3B shows a cross-sectional view of a portion 3A of the structure illustrated in FIG. 3 in accordance with some arrangements of the present disclosure. In some arrangements, the curved corner 400c of the conductive layer 400 is exposed by the barrier layer 500. In some arrangements, the curved corner 400c of the conductive layer 400 is exposed by the barrier material layer 500A where melting the barrier material layer 500A. When the curved corner 400c of the conductive layer 400 is at least protruded beyond the surface 401 of the conductive layer 400, and/or when the amount of the barrier material layer 500A is relatively small, the molten barrier material layer 500A may form a relatively thin layer over the conductive layer 400 and thereby expose the curved corner 400c.

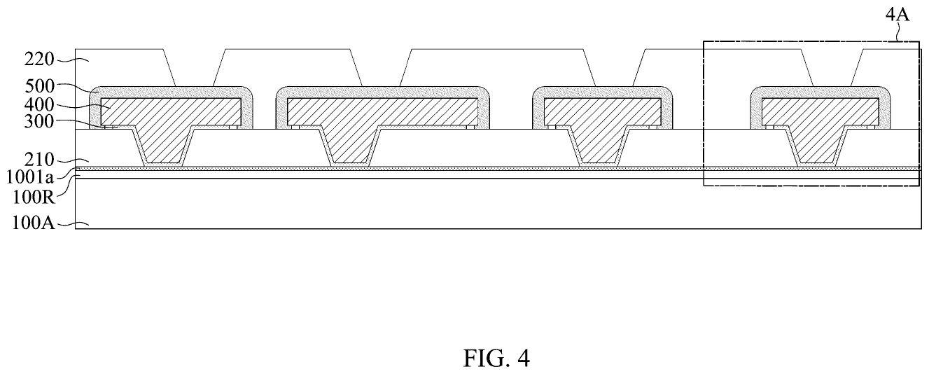

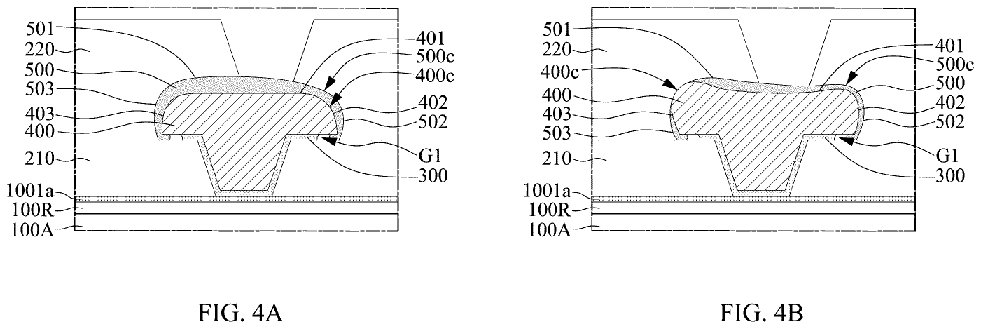

Referring to FIG. 4 and FIG. 4A, FIG. 4A shows a cross-sectional view of a portion 4A of the structure illustrated in FIG. 4 in accordance with some arrangements of the present disclosure. A dielectric layer 220 may be formed over and exposing one or more portions of one or more convex curved surfaces (e.g., the surfaces 501) of the barrier layer 500. In some arrangements, the dielectric layer 220 has openings or through holes that expose an upper surface (e.g., the surface 501) of each of the barrier portions of the barrier layer 500.

In some arrangements, referring to FIG. 4B, FIG. 4B shows a cross-sectional view of a portion 4A of the structure illustrated in FIG. 4 in accordance with some arrangements of the present disclosure. In some arrangements, a portion of an irregular upper surface (e.g., the surface 501) of the barrier layer 500 (or the barrier portion) is exposed by the opening or through hole of the dielectric layer 220.

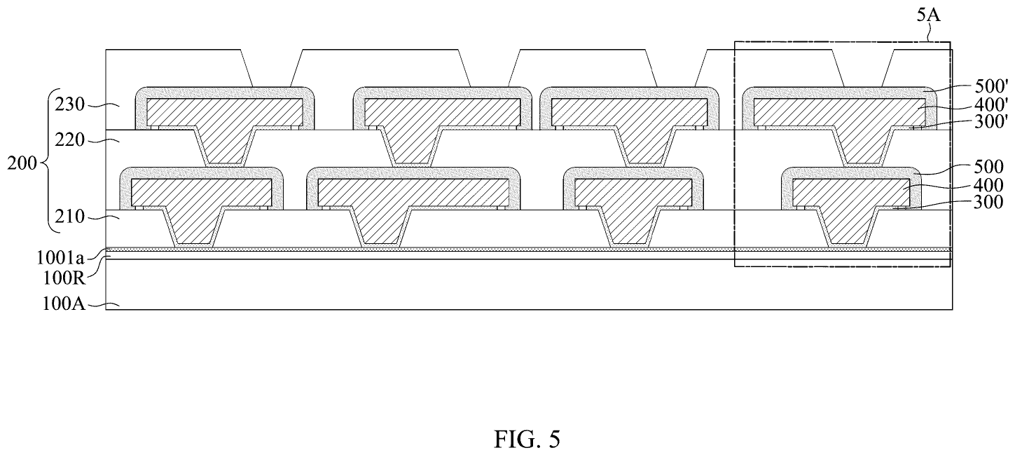

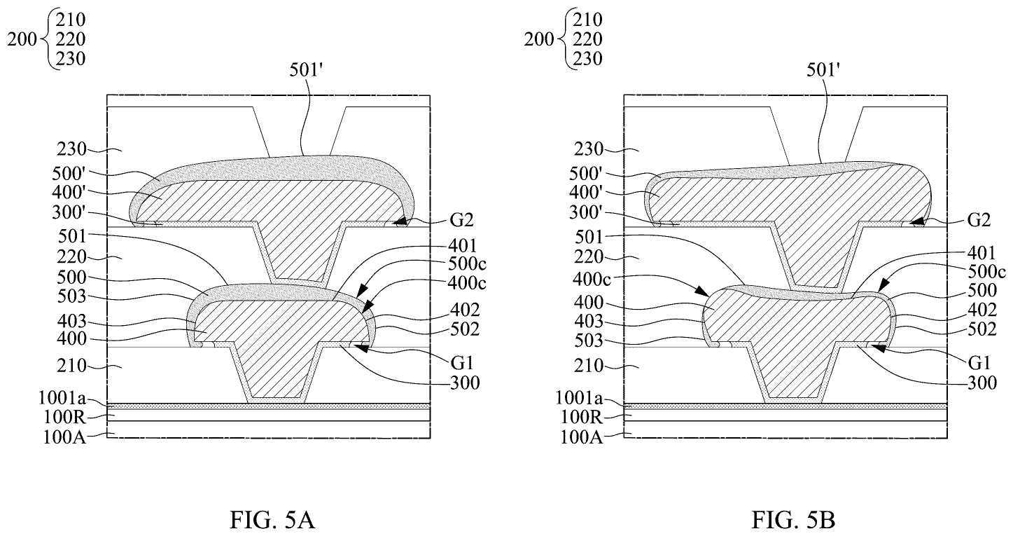

Referring to FIG. 5 and FIG. 5A, FIG. 5A shows a cross-sectional view of a portion 5A of the structure illustrated in FIG. 5 in accordance with some arrangements of the present disclosure. An additional conductive layer 400′ may be formed on and conformal with the exposed portion of the convex curved surface (e.g., the surface 501) of the barrier layer 500, an additional barrier layer 500′ may be formed over the conductive layer 400′, a seed layer 300′ may be formed between the conductive layer 400′ and the dielectric layer 220, and a dielectric layer 230 may be formed over and exposing one or more portions of one or more convex curved surfaces (e.g., the surfaces 501′) of the barrier layer 500′. In some arrangements, the seed layer 300′ may be formed to have a lateral side, and the lateral side and the conductive layer 400′ collectively define a gap G2. The conductive layer 400′ and the barrier layer 500′ may be formed by operations similar to those illustrated in FIGS. 1B-3B, the dielectric layer 230 may be formed by operations similar to those illustrated in FIG. 4, and the description thereof is omitted hereinafter. In some arrangements, the conductive layer 400′ and the barrier layer 500′ may be formed by deposition.

In some arrangements, referring to FIG. 5B, FIG. 5B shows a cross-sectional view of a portion 5A of the structure illustrated in FIG. 5 in accordance with some arrangements of the present disclosure. In some arrangements, a portion of an irregular upper surface (e.g., the surface 501′) of the barrier layer 500′ (or the barrier portion) is exposed by the opening or through hole of the dielectric layer 230. The dielectric layers 210, 220, and 230 may collectively form a dielectric structure 200.

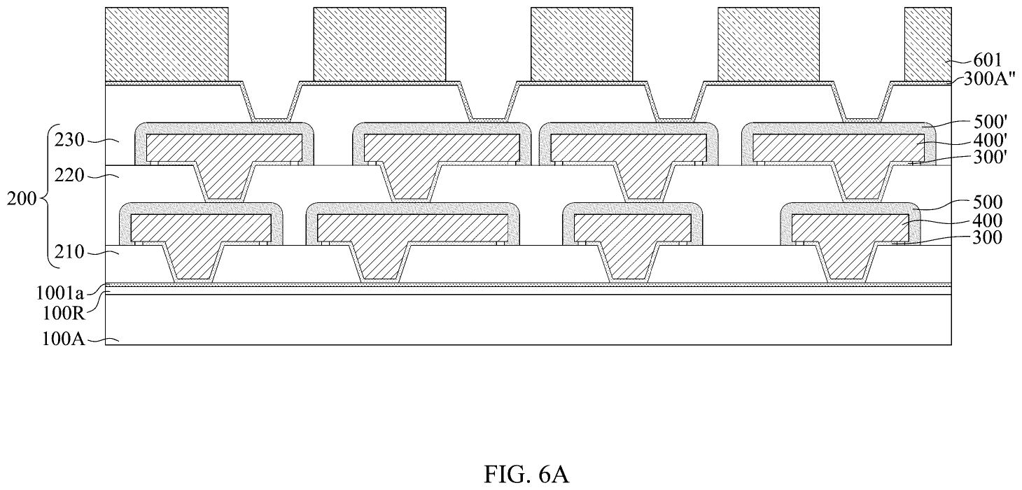

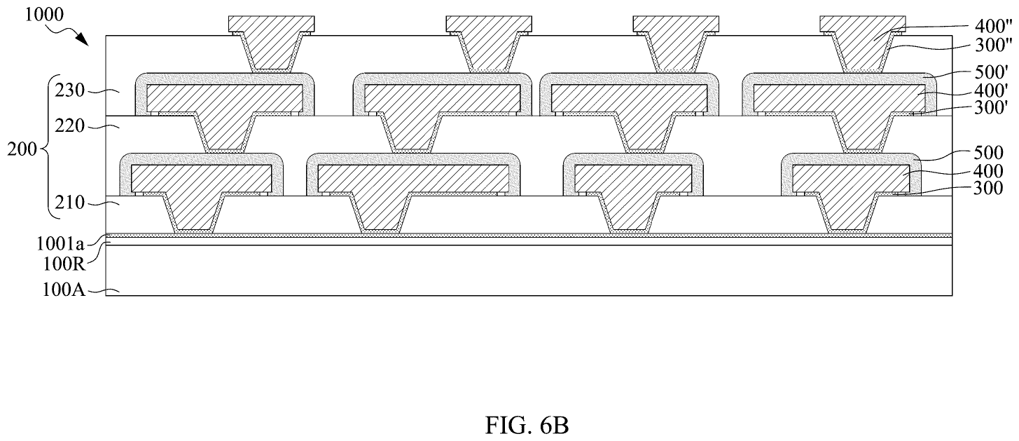

Referring to FIG. 6A, a seed material layer 300A″ may be formed over the dielectric layer 230 and the exposed portions of the barrier layer 500′, and a sacrificial pattern 601 may be formed on the seed material layer 300A″.

Referring to FIG. 6B, a conductive pad (e.g., the conductive layer 400″) may be formed over the conductive layer 400′ and configured to electrically connect to an electronic component 40 through a solder material (e.g., connection elements 31). In some arrangements, the conductive layer 400″ is formed in openings defined by the sacrificial pattern 601, the sacrificial pattern 601 is then removed, and then the seed material layer 300A″ is partially removed to form the seed layer 300″. The seed material layer 300A″ may be partially removed by an etching operation, such that the seed layer 300″ is recessed with respect to the conductive layer 400″. The materials of the seed layers 300′ and 300″ are the same as or similar to that of the seed material layers 300A, the materials of the conductive layers 400′ and 400″ are the same as or similar to that of the conductive layer 400, the material of the barrier layer 500′ is the same as or similar to that of the barrier layer 500, the materials of the dielectric layers 220 and 230 are the same as or similar to that of the dielectric layer 210, and thus the description thereof is omitted hereinafter. As such, a redistribution layer (RDL) 1000 may be formed over the carrier 100A.

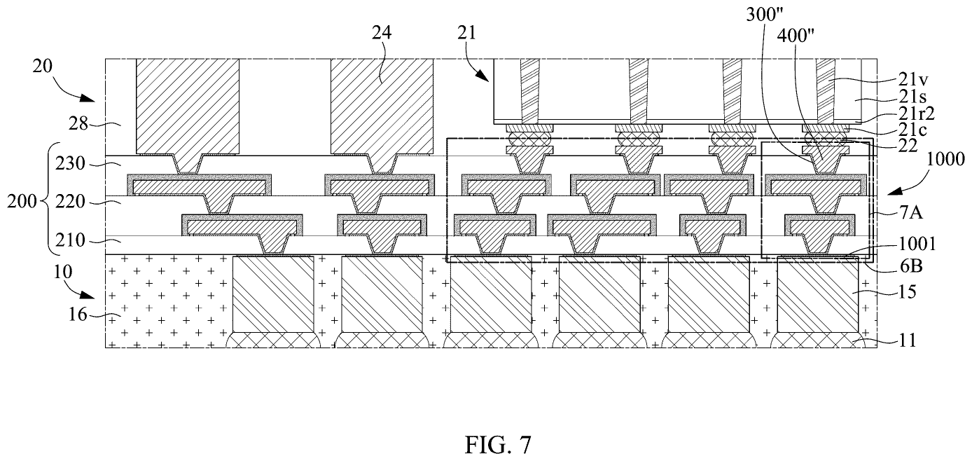

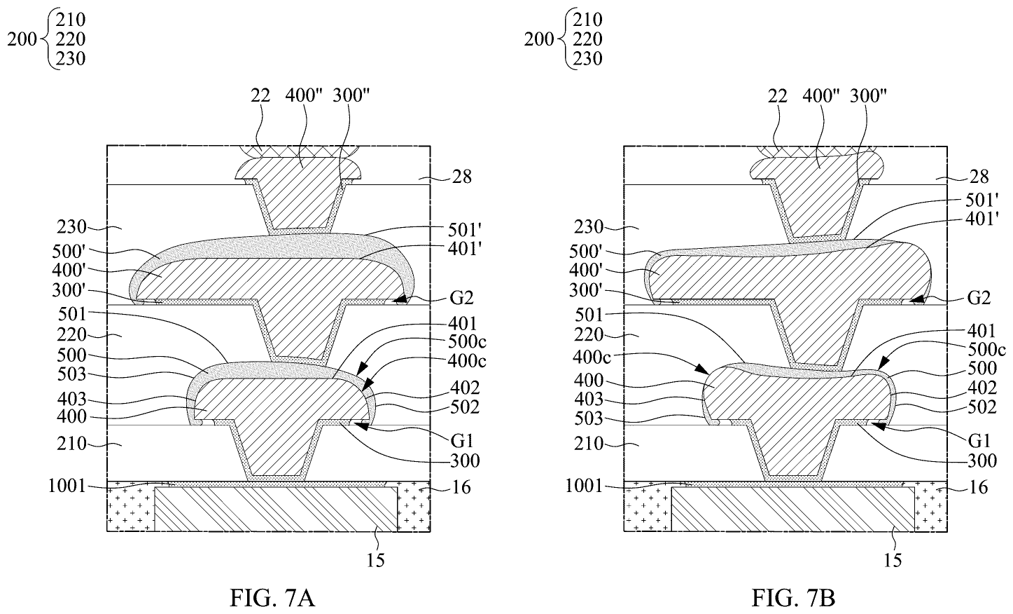

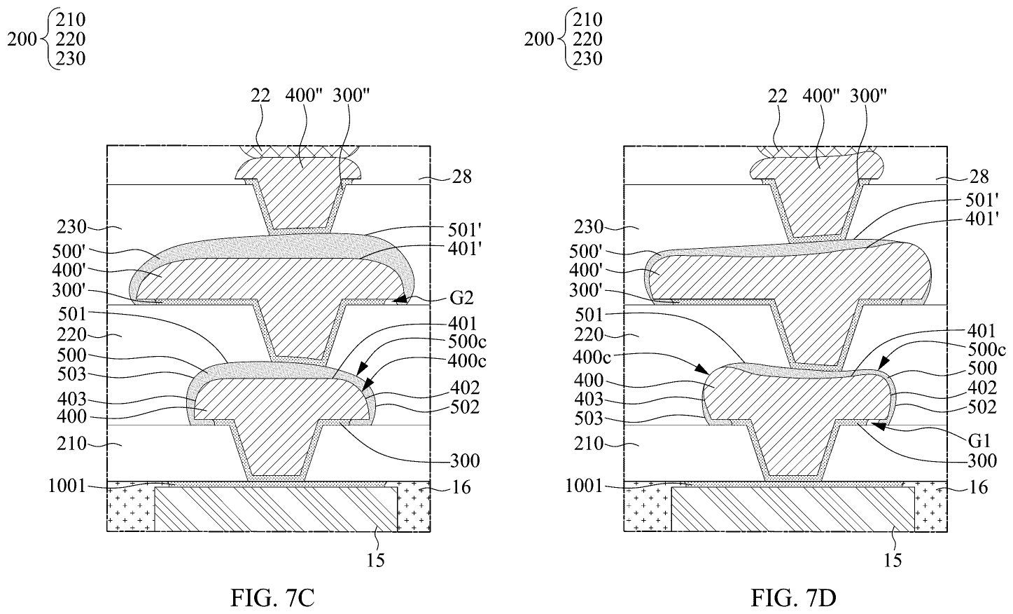

Referring to FIG. 7 and FIG. 7A, FIG. 7A shows a cross-sectional view of a portion 7A of the structure illustrated in FIG. 7 in accordance with some arrangements of the present disclosure. In some arrangements, FIG. 7 illustrates one or more stages following the stage illustrated in FIG. 6B. In some arrangements, FIG. 7 illustrates a portion of a package structure formed by an exemplary method in accordance with some arrangements of the present disclosure.

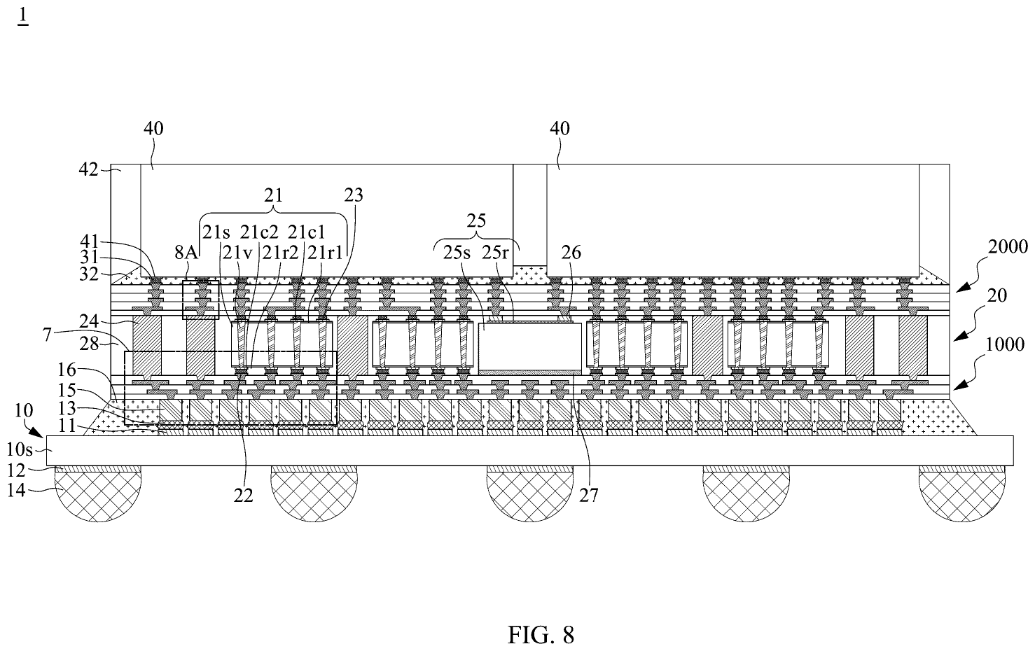

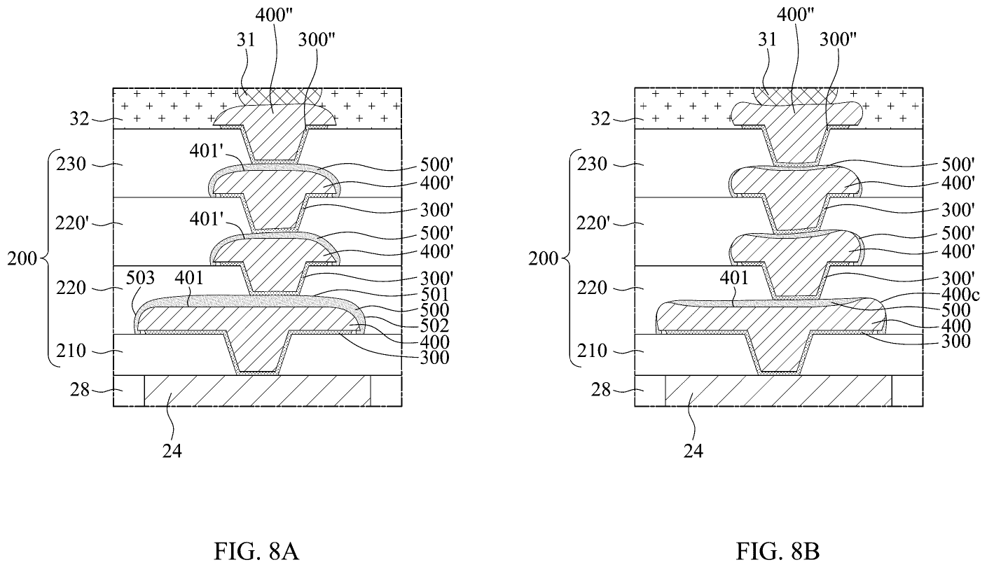

The carrier 100A and the release film 100R may be removed from the RDL 1000. A substrate 10 may be connected to a substrate 20 by the RDL 1000. In some arrangements, the substrate 10 includes conductive pillars 15 that are connected to the conductive layer 400 of the RDL 1000, and the substrate 20 includes conductive pillars 24 and at least an electronic component 21 that are connected to the barrier layer 500′ and the conductive layer 400′ of the RDL 1000. The RDL 1000 may include a portion 6B which may include a structure similar to that illustrated in FIG. 6B. The portion 6B of the RDL 1000 may include the portion 7A having a structure illustrated in FIG. 7A. Please be noted that FIG. 7 and FIG. 7A only show portions of the substrates 10 and 20 to illustrate the connection between the substrates 10 and 20 by the RDL 1000, more structural details may be shown in FIG. 8 in accordance with some arrangements of the present disclosure. In some arrangements, referring to FIG. 1A and FIG. 7, a sacrificial pattern may be disposed on the seed layer 1001a to define openings that expose the seed layer 1001a, and a conductive material may be disposed in the openings to form the conductive pillars 15. Next, the sacrificial pattern is removed, and then the seed layer 1001a is partially removed by etching to form seed layers 1001 between the dielectric layer 210 and the conductive pillars 15. Next, the conductive pillars 15 are connected to the conductive pads 11, and the protective element 16 is formed to encapsulate the conductive pillars 15.

In some arrangements, as shown in FIG. 7 and FIG. 7A, the electronic component 21 is connected to the RDL 1000 through connection elements 22 (e.g., conductive bumps or solder bumps). In some arrangements, the connection element 22 is electrically connected to the conductive layer 400″ of the RDL 1000. In some arrangements, as shown in FIG. 7, the conductive pillar 24 includes a portion that extends into an opening or a through hole of the dielectric layer 230 to connect to the barrier layer 500′ and the conductive layer 400′ of the RDL 1000.

In some arrangements, referring to FIG. 7B, FIG. 7B shows a cross-sectional view of a portion 7A of the structure illustrated in FIG. 7 in accordance with some arrangements of the present disclosure. In some arrangements, the connection element 22 is connected to the conductive layer 400″ and the seed layer 300″.

In some arrangements, referring to FIG. 7C, FIG. 7C shows a cross-sectional view of a portion 7A of the structure illustrated in FIG. 7 in accordance with some arrangements of the present disclosure. In some arrangements, the barrier layer 500 contacts the seed layer 300. In some arrangements, the barrier layer 500′ contacts the seed layer 300′. In some arrangements, the thermal treatment P1 includes heating the barrier material layer 500A until the barrier material layer 500A flows toward the seed layer 300. In some arrangements, the thermal treatment P1 includes heating the barrier material layer 500A until the barrier material layer 500A contacts the seed layer 300, such that the as-formed barrier layer 500 contacts the seed layer 300.

In some arrangements, referring to FIG. 7D, FIG. 7D shows a cross-sectional view of a portion 7A of the structure illustrated in FIG. 7 in accordance with some arrangements of the present disclosure. In some arrangements, the barrier layer 500 contacts the seed layer 300. In some arrangements, the barrier layer 500′ contacts the seed layer 300′.

Referring to FIG. 8 and FIG. 8A, FIG. 8A shows a cross-sectional view of a portion 8A of the structure illustrated in FIG. 8 in accordance with some arrangements of the present disclosure. In some arrangements, FIG. 8 illustrates one or more stages following the stage illustrated in FIG. 6B. In some arrangements, FIG. 8 illustrates a package structure 1 formed by an exemplary method in accordance with some arrangements of the present disclosure.

A substrate 20 may be connected to the RDL 1000. In some arrangements, the substrate 20 includes electronic components 21, connection elements 22, 23 and 26 (conductive bumps or solder bumps), conductive pillars 24, a bridge component 25, an adhesive layer 27, and an encapsulant 28 formed on the RDL 1000. The electronic component 21 may include a substrate layer 21s, conductive layers 21r1 and 21r2 (or circuit layers or wiring layers), conductive vias 21v connecting the conductive layers 21r1 and 21r2, and conductive pads 21cl and 21c2 connected to the conductive vias 21v. The bridge component 25 may include a substrate layer 25s and a conductive layer 25r (or a circuit layer or a wiring layer). In some arrangements, the electronic components 21 are disposed or formed on and electrically connected to the RDL 1000 (or the conductive layer 400″) through the connection elements 22 (or the conductive bumps). In some arrangements, the connection elements 23 (or the conductive bumps) are formed on and connected to the electronic components 21. In some arrangements, the bridge component 25 is disposed or formed on and electrically connected to the RDL 1000 (or the conductive layer 400″) through the adhesive layer 27 (e.g., a die attach film), and the connection elements 26 (or the conductive bumps) are formed on and connected to the conductive layer 25r. In some arrangements, the conductive pillars 24 are disposed or formed on and electrically connected to the RDL 1000 (or the conductive layer 400″). In some arrangements, the encapsulant 28 is formed on the RDL 1000 and encapsulating the electronic components 21, the connection elements 22, 23 and 26, the conductive pillars 24, the bridge component 25, and the adhesive layer 27. The electronic components 21 may be or include passive components, such as capacitors. The bridge component 25 may be or include a bridge die. At this stage, the substrate 20 is connected to the RDL 1000 which is disposed on the carrier 100A.

Next, still referring to FIG. 8, an RDL 2000 may be disposed or formed on and electrically connected to the substrate 20. In some arrangements, the RDL 2000 is formed by operations similar to those illustrated in FIG. 1A to FIG. 6B for forming the RDL 1000. The RDL 2000 may include a dielectric structure 200 including a plurality of dielectric layers (e.g., dielectric layers 210, 220, 220′ and 230 shown in FIG. 8A), a plurality of seed layers (e.g., seed layers 300, 300′, and 300″ shown in FIG. 8A), a plurality of conductive layers (e.g., conductive layers 400, 400′, and 400″ shown in FIG. 8A), and a plurality of barrier layers (e.g., barrier layers 500 and 500′ shown in FIG. 8A). In some arrangements, referring to FIG. 8A, which shows a cross-sectional view of a portion 8A of the RDL 2000, the conductive layers 400, 400′, and 400″ are stacked vertically and connected to each other, each of the barrier portions of the barrier layers 500 and 500′ covers an upper surface and sidewalls of each of the trace portions of the conductive layers 400 and 400′. In some arrangements, the barrier layers 500 and 500′ have convex curved surfaces (e.g., surfaces 501, 502, and 503). In some arrangements, the RDL 2000 electrically connects to the conductive pillars 24. In some arrangements, the RDL 2000 electrically connects to the electronic components 21 through the connection elements 23. In some arrangements, the RDL 2000 electrically connects to the bridge component 25 through the connection elements 26.

Next, still referring to FIG. 8, electronic components 40 may be connected to the RDL 2000 through connecting the conductive pads 41 to the connection elements 31 (conductive bumps or solder bumps). In some arrangements, an underfill 32 covers the conductive pads 41 and the connection elements 31, and an encapsulant 42 encapsulates the electronic components 40. In some arrangements, the electronic component 40 may be or include an active component, for example, a processing component (e.g., an ASIC), a memory component (e.g., a HMB), or a combination thereof. In some arrangements, the electronic components 40 may be connected to each other through the bridge component 25 by transmitting signals through the connection elements 31, the RDL 2000, the connection elements 26, and the bridge component 25.

Next, still referring to FIG. 8, the carrier 100A may be removed from the RDL 1000, a substrate 10 may be connected to the RDL 1000, such that the substrate 10 may be electrically connected to the substrate 20 through the RDL 1000. In some arrangements, the substrate 10 includes a substrate layer 10s, conductive pads 11 and 12, connection elements 13, electrical contacts 14, conductive pillars 15, and protective element 16. In some arrangements, the conductive pillars 15 are formed or disposed on the RDL 1000, the conductive pads 11 are connected to the conductive pillars 15 through the connection elements 13 (e.g., conductive bumps or solder bumps), and the protective element 16 (e.g., an underfill or an encapsulant) encapsulates the conductive pillars 15, the connection elements 13, and the conductive pads 11. The electrical contacts 14 may be further connected to the substrate layer 10s through the conductive pads 12. The electrical contacts 14 may be or includes solder balls. As such, the package structure 1 is formed.

In some arrangements, the package structure 1 includes the substrates 10 and 20, the electronic components 40, the RDL 1000 connecting the substrate 10 to the substrate 20, and the RDL 2000 connecting the electronic components 40 to the RDL 2000. In some arrangements, the RDL 1000 includes at least the conductive layer 400 over the substrate 10 and the barrier layer 500 on sidewalls (e.g., the surfaces 402 and 403) of the conductive layer 400, and the barrier layer 500 has one or more convex curved surface (e.g., the surfaces 501, 502, and 503).

In some arrangements, the convex curved surface (e.g., the surface 501) of the barrier layer 500 covers an upper surface (e.g., the surface 401) of the conductive layer 400. In some arrangements, the RDL 1000 further includes the conductive layer 400′ on and conformal with the convex curved surface (e.g., the surface 501) of the barrier layer 500. In some arrangements, the RDL 1000 further includes the barrier layer 500′ over an upper surface (e.g., the surface 401′) of the conductive layer 400′, and the barrier layer 500′ has a convex curve surface (e.g., the surface 501′) covering the upper surface (e.g., the surface 401′) of the conductive layer 400′. In some arrangements, the surface 501 is non-parallel to the surface 501.

In some arrangements, referring to FIG. 8B, which shows a cross-sectional view of a portion 8A of the RDL 2000 in accordance with some arrangements of the present disclosure. In some arrangements, the conductive layer 400 includes a curved corner 400c at an elevation higher than an elevation of an upper surface (e.g., the surface 401) of the conductive layer 400 with respect to the substrate 10, and the curved corner 400c is exposed by the barrier layer 500.

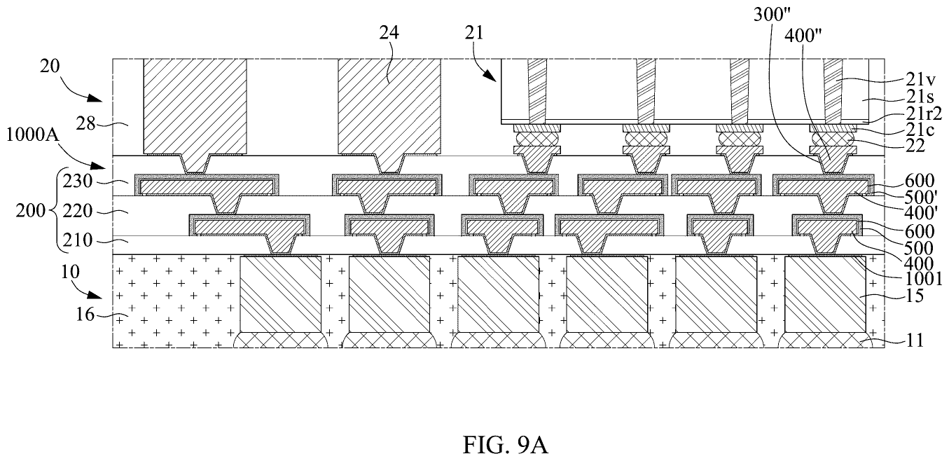

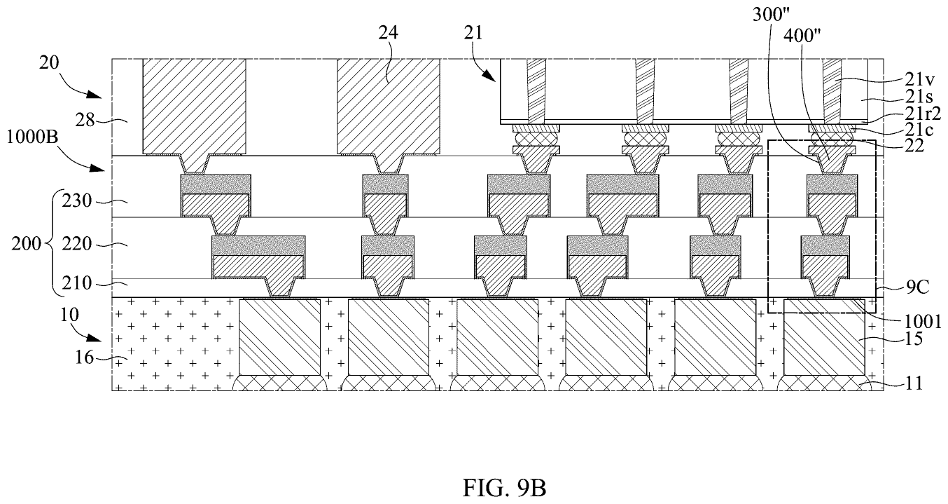

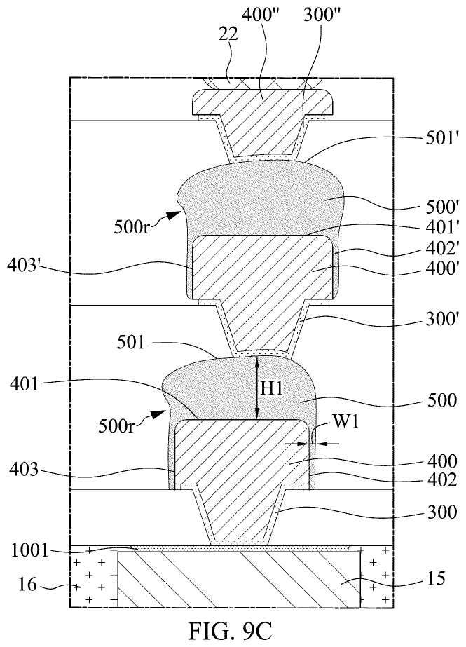

FIG. 9A illustrates one or more stages of an exemplary method of forming a package structure in accordance with some arrangements of the present disclosure.

Operation similar to those illustrated in FIG. 1A to FIG. 7 may be performed, and an alloy layer 600 may be formed between the conductive layer 400 and the barrier layer 500. In some arrangements, an alloy layer 600 may be formed between each of the conductive layers 400 and each of the barrier layers 500. In some arrangements, an alloy layer 600 may be formed between each of the conductive layers 400′ and each of the barrier layers 500′. The alloy layer 600 and the conductive layer 400 may include a same element. The alloy layer 600 and the barrier layer 500 may include a same element. As such, an RDL 1000A may be formed. In some arrangements, the RDL 1000A may be used to replace the RDL 1000 and/or the RDL 2000 in forming the package structure 1 illustrated in FIG. 8.

FIG. 9B to FIG. 9C illustrate various stages of an exemplary method of forming a package structure in accordance with some arrangements of the present disclosure.

Referring to FIG. 9B and FIG. 9C, FIG. 9C shows a cross-sectional view of a portion 9C of the structure illustrated in FIG. 9B in accordance with some arrangements of the present disclosure. Operation similar to those illustrated in FIG. 1A to FIG. 2C may be performed to form a structure illustrated in FIG. 2, and then operations similar to those illustrated in FIG. 3 may be performed to form a barrier layer 500 by melting the barrier material layer 500A, such that the barrier layer 500 extends over the sidewalls (e.g., the surfaces 402 and 403) of the conductive layer 400. In some arrangements, a relatively small amount of the molten barrier material layer 500A flows over the sidewalls of the conductive layer 400, and a width W1 (or a thickness) of a lower portion of the barrier layer 500 on the sidewall of the conductive layer 400 is less than a height H1 (or a thickness) of an upper portion of the barrier layer 50 on the upper surface (e.g., the surface 401) of the conductive layer 400. In some arrangements, the RDL 1000B may be used to replace the RDL 1000 and/or the RDL 2000 in forming the package structure 1 illustrated in FIG. 8.

In some arrangements, as shown in FIG. 9C, In some arrangements, a molten barrier material layer 500A may tend to aggregate into a roughly spherical shape due to its cohesion, and thus the surface 501 that is a curved surface convex upwards may be formed when melting the barrier material layer 500A. In some arrangements, a recess 500r may be formed between an upper portion and a lower portion of the barrier layer 500. In some arrangements, the lower portion of the barrier layer 500 may taper toward the dielectric layer 210.

According to some arrangements of the present disclosure, by melting a barrier material layer 500A to form a barrier layer 500 on sidewalls of a conductive layer 400 of an RDL 1000, complicated operations including deposition and etching for forming a barrier layer on sidewalls of a conductive layer can be omitted, thus the process can be simplified, and the cost can be reduced as well.

In addition, according to some arrangements of the present disclosure, the barrier layer 500 is formed by melting the barrier material layer 500A, thus the molten barrier material layer 500A can flow into relatively small gaps between the trace portions having a relatively small pitch (e.g., a fine pitch). Therefore, metal atoms diffusion (e.g., copper diffusion) between the trace portions of the conductive layer 400 with a relatively small pitch can be prevented effectively, thus undesired short between the adjacent trace portions of the conductive layer 400 can be prevented, and a package structure 1 with RDLs having a relatively small pitch can be achieved without undesirable short-circuit issues.

Moreover, according to some arrangements of the present disclosure, the barrier material layer 500A has a relatively low melting point, thus the melting operation can be performed under a relatively low temperature. Therefore, elements of the structures (e.g., the conductive layer 400) can be prevented from being damaged by operations for forming the barrier layer 500 (e.g., relatively large energy provided by a high temperature operation), thus the yield can be increased, and the reliability of the as-formed package structure can be increased.

Furthermore, in some cases, a dielectric layer may be formed prior to formation of a conductive layer, and a trench is defined between the dielectric layer and the sidewall of the conductive layer followed by filling a barrier material into the trench to form a barrier layer on the sidewall of the conductive layer. The trench may have a relatively large aspect ratio, and thus the as-formed barrier layer may have voids, which can adversely influence the barrier function. In contrast, according to some arrangements of the present disclosure, the portions of the barrier layer 500 on the sidewalls of the conductive layer 400 are formed by allowing the molten barrier material layer to flow over the sidewalls. Therefore, the aforesaid issues can be prevented, and thus the yield can be increased.

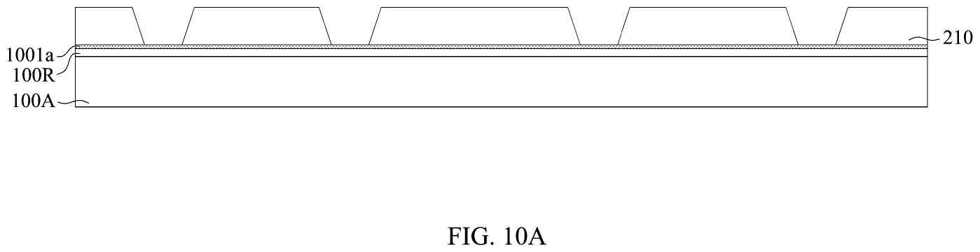

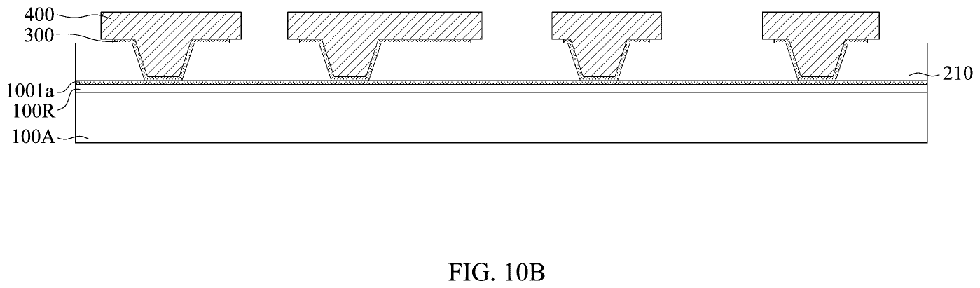

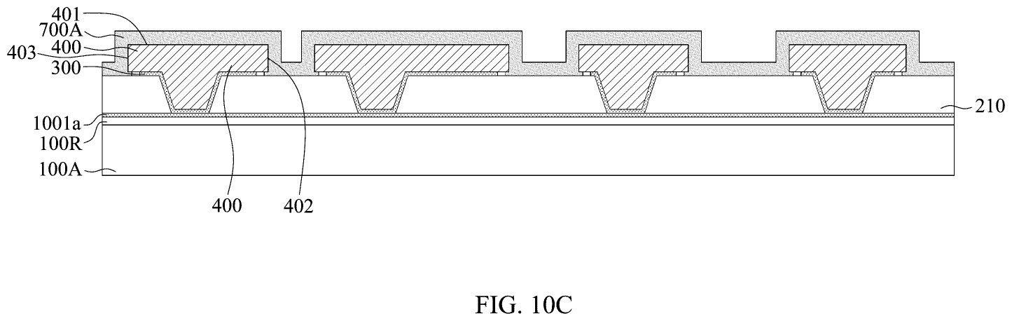

FIG. 10A to FIG. 16B illustrate various stages of an exemplary method of forming a package structure in accordance with some arrangements of the present disclosure.

Referring to FIG. 10A, operations similar to those illustrated in FIG. 1A may be performed to form a dielectric layer 210 over a carrier 100A.

Referring to FIG. 10B, operations similar to those illustrated in FIG. 1B to FIG. 2 may be performed to form a conductive layer 400 over the carrier 100A with the seed layer 300 formed therebetween, except that a barrier material layer is not formed on the conductive layer 400. In some arrangements, the conductive layer 400 includes a plurality of trace portions formed on the dielectric layer 210. The trace portions may be separated or spaced apart from each other in a cross-sectional view perspective. The trace portions may be disposed or arranged on the dielectric layer 210 in a side-by-side manner.

Referring to FIG. 10C, a barrier material layer 700A may be formed over an upper surface (e.g., the surface 401) and sidewalls (e.g., the surfaces 402 and 403) of the conductive layer 400. In some arrangements, the barrier material layer 700A is formed over the dielectric layer 210, the upper surface (e.g., the surface 401) and the sidewalls (e.g., the surfaces 402 and 403) of each of the trace portions of the conductive layer 400. The barrier material layer 700A may be formed by sputtering, deposition, or any suitable technique. In some arrangements, the barrier material layer 700A is formed by sputtering. In some arrangements, the barrier material layer 700A may be deposited to partially extend below the conductive layer 400. The barrier material layer 700A may have a thickness of less than 1 μm, for example, about 0.1 μm. The barrier material layer 700A may be or include titanium (Ti), titanium nitride (TiN), nickel-vanadium alloy (NiV), or an alloy thereof.

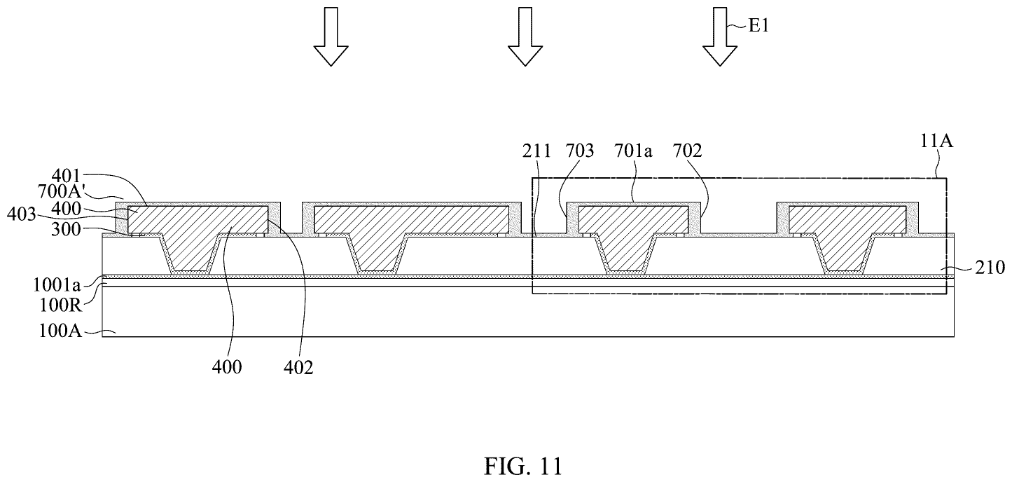

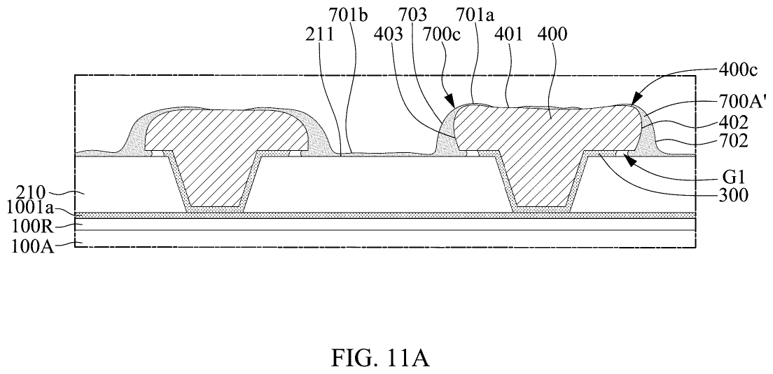

Referring to FIG. 11 and FIG. 11A, FIG. 11A shows a cross-sectional view of a portion 11A of the structure illustrated in FIG. 11 in accordance with some arrangements of the present disclosure. A dry etch process E1 may be performed to at least partially remove the barrier material layer 700A from the upper surface (e.g., the surface 401) of the conductive layer 400. In some arrangements, performing the dry etch process E1 at least partially removes the barrier material layer 700A from the upper surface (e.g., the surface 401) of each of the trace portions of the conductive layer 400. In some arrangements, performing the dry etch process E1 at least partially removes a portion of the barrier material layer 700A from the surface 401. In some arrangements, performing the dry etch process E1 partially removes the barrier material layer 700A from lateral surfaces (e.g., surfaces 702 and 703) of the barrier material layer 700A. In some arrangements, partially removing the barrier material layer 700A includes performing the dry etch process E1 in a direction from an upper surface (e.g., a surface 701a) of the barrier material layer 700A toward the upper surface (e.g., the surface 211) of the dielectric layer 210 along the lateral surfaces (e.g., the surfaces 702 and 703) of the barrier material layer 700A.

In some arrangements, as shown in FIG. 11A, a residual portion 700A′ of the barrier material layer 700A having a non-uniform thickness is formed over the upper surface (e.g., the surface 401) of the conductive layer 400 by the dry etch process E1. In some arrangements, the residual portion 700A′ of the barrier material layer 700A has an uneven or non-uniform surface 701a over the surface 401 of the conductive layer 400. In some arrangements, the residual portion 700A′ of the barrier material layer 700A has an uneven or non-uniform surface 701b on the dielectric layer 210 and between adjacent trace portions. In some arrangements, as shown in FIG. 11A, the residual portion 700A′ of the barrier material layer 700A tapering toward the upper surface (e.g., the surface 401) of the conductive layer 400 is formed on the sidewalls (e.g., the surfaces 402 and 403) of the conductive layer 400 by the dry etch process E1. In some arrangements, a surface 702 of the residual portion 700A′ of the barrier material layer 700A is non-parallel to the surface 402, and a surface 703 of the barrier material layer 700A is non-parallel to the surface 403. In some arrangements, a distance between the surface of the curved corner 400c of the conductive layer 400 and a curved corner 700c (also referred to as “a curved portion”) of the residual portion 700A′ of the barrier material layer 700A is less than a distance between the surface 702 and the surface 402.

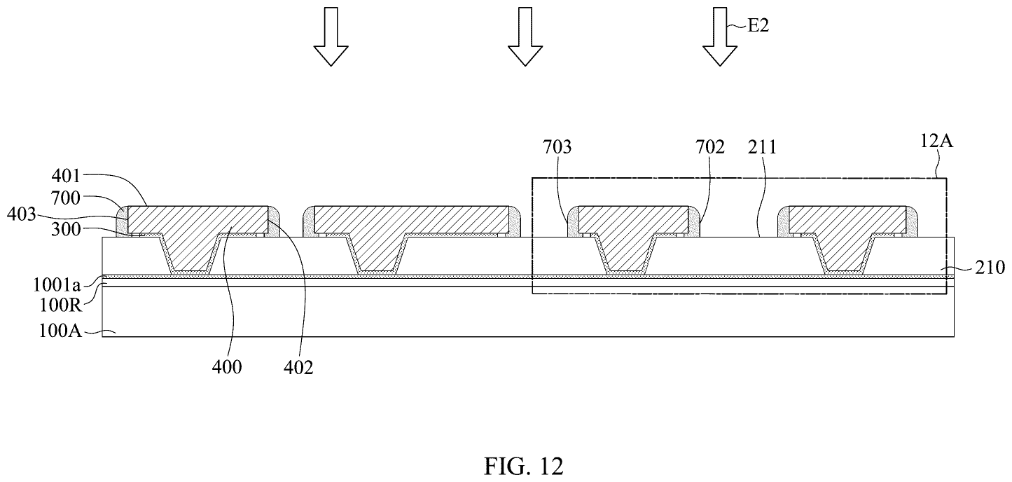

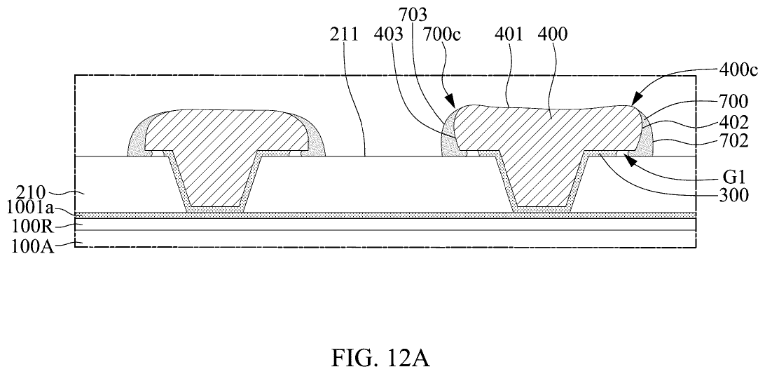

Referring to FIG. 12 and FIG. 12A, FIG. 12A shows a cross-sectional view of a portion 12A of the structure illustrated in FIG. 12 in accordance with some arrangements of the present disclosure. The barrier material layer 700A may be further partially removed to form a barrier layer 700 on the sidewalls (e.g., the surfaces 402 and 403) of the conductive layer 400 without contacting or covering the upper surface (e.g., the surface 401) of the conductive layer 400. In some arrangements, a wet etch process E2 is performed to entirely remove the barrier material layer 700A (or the residual portion 700A′) from the upper surface (e.g., the surface 401) of the conductive layer 400 after performing the dry etch process E1.

In some arrangements, the wet etch process E2 is performed to entirely remove the barrier material layer 700A (or the residual portion 700A′) from the upper surface (e.g., the surface 401) of each of the trace portions of the conductive layer 400 after performing the dry etch process E1. In some arrangements, the wet etch process E2 further removes a portion of the barrier material layer 700A (or the residual portion 700A′) on the dielectric layer 210 and between the trace portions of the conductive layer 400. In some arrangements, the wet etch process E2 removes a portion of the barrier material layer 700A between trace portions of the conductive layer 400 to expose an upper surface (e.g. a surface 211) of the dielectric layer 210.

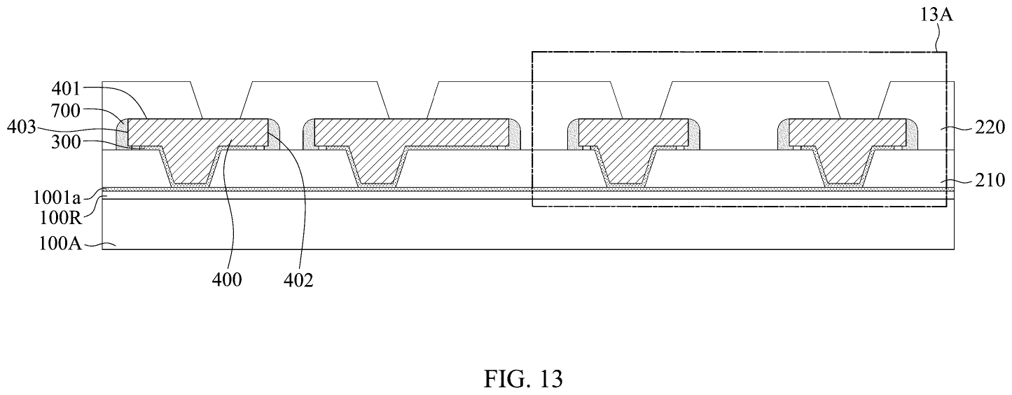

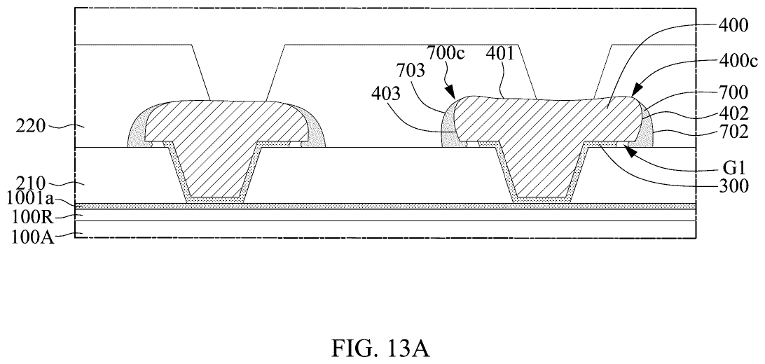

Referring to FIG. 13 and FIG. 13A, FIG. 13A shows a cross-sectional view of a portion 13A of the structure illustrated in FIG. 13 in accordance with some arrangements of the present disclosure. Operations similar to those illustrated in FIG. 4 may be performed to form a dielectric layer 220 over and exposing one or more portions of the upper surface (e.g., the surface 401) of the conductive layer 400.

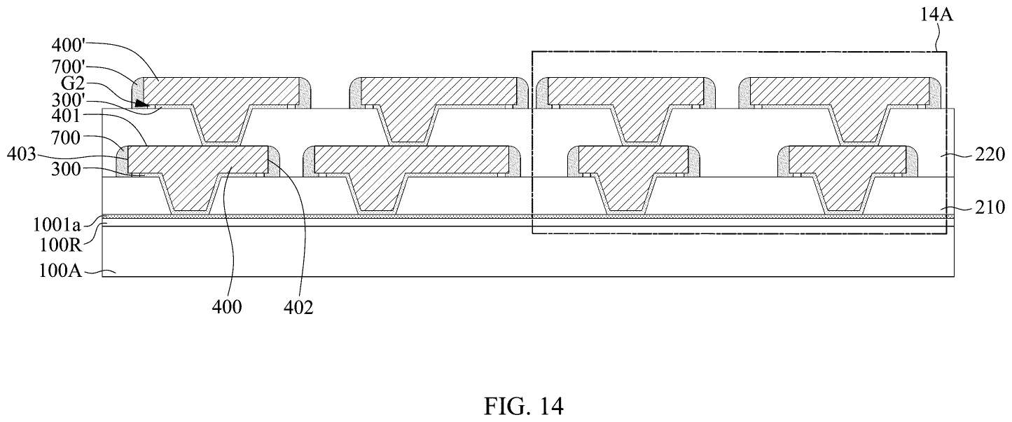

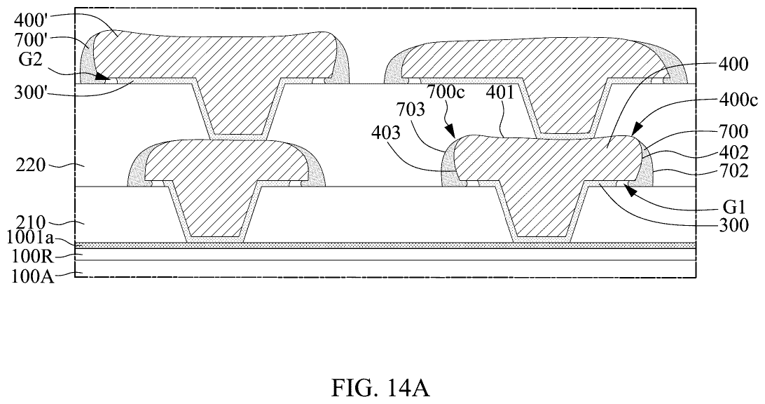

Referring to FIG. 14 and FIG. 14A, FIG. 14A shows a cross-sectional view of a portion 14A of the structure illustrated in FIG. 14 in accordance with some arrangements of the present disclosure. Operations similar to those illustrated in FIG. 10B to FIG. 12A may be performed to form a conductive layer 400′ on and conformal with the upper surface (e.g., the surface 401) of the conductive layer 400, a barrier layer 700′ on sidewalls of the conductive layer 400′, and a seed layer 300′ between the dielectric layer 220 and the conductive layer 400′.

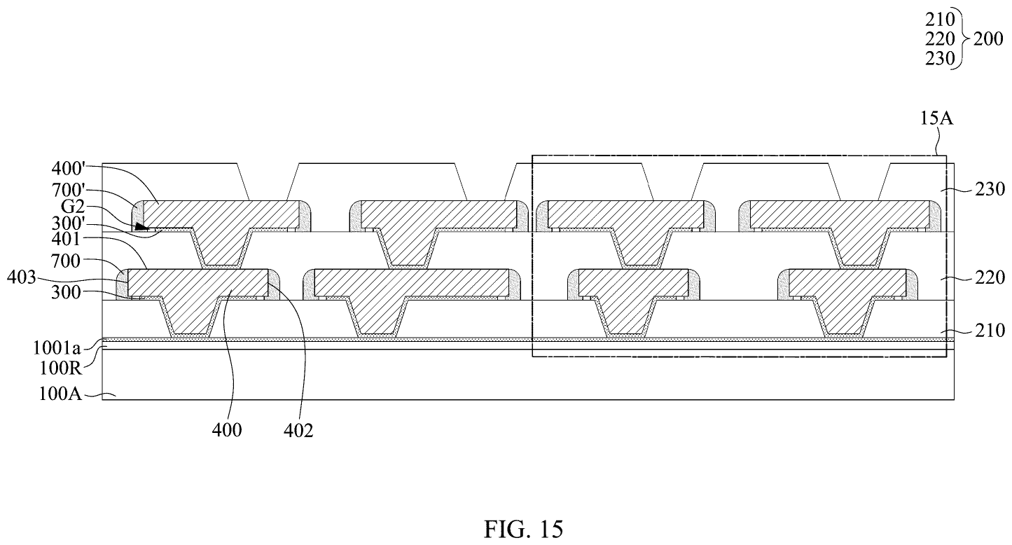

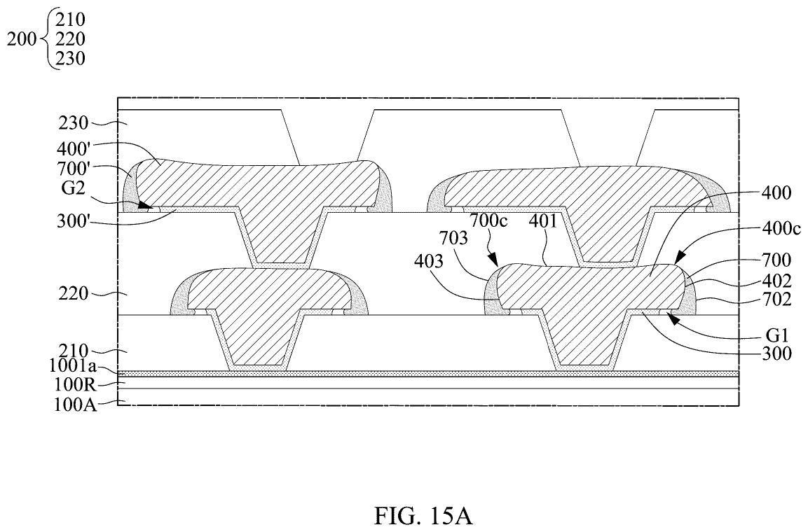

Referring to FIG. 15 and FIG. 15A, FIG. 15A shows a cross-sectional view of a portion 15A of the structure illustrated in FIG. 15 in accordance with some arrangements of the present disclosure. Operations similar to those illustrated in FIG. 5 may be performed to form a dielectric layer 230 over and exposing one or more portions of the upper surface of the conductive layer 400′. The dielectric layers 210, 220, and 230 may collectively form a dielectric structure 200.

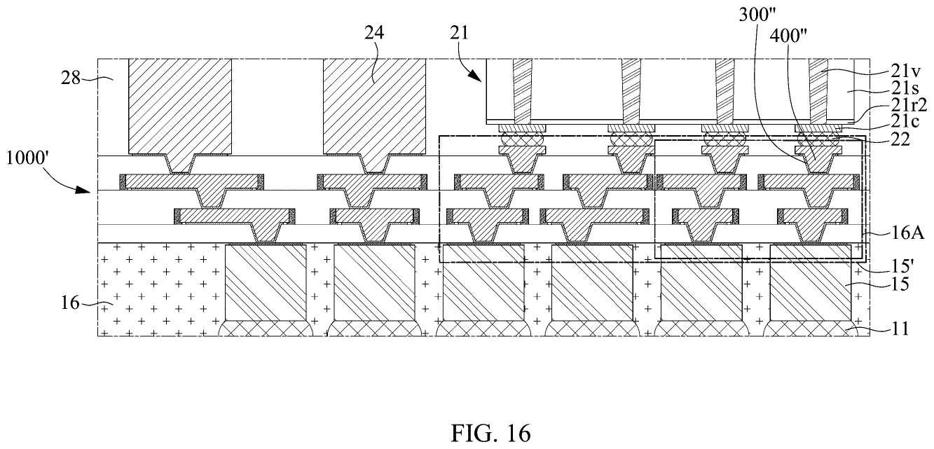

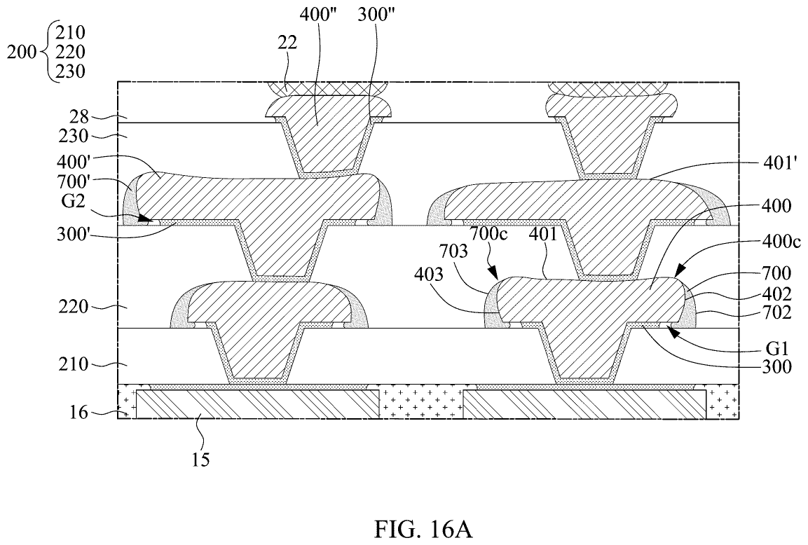

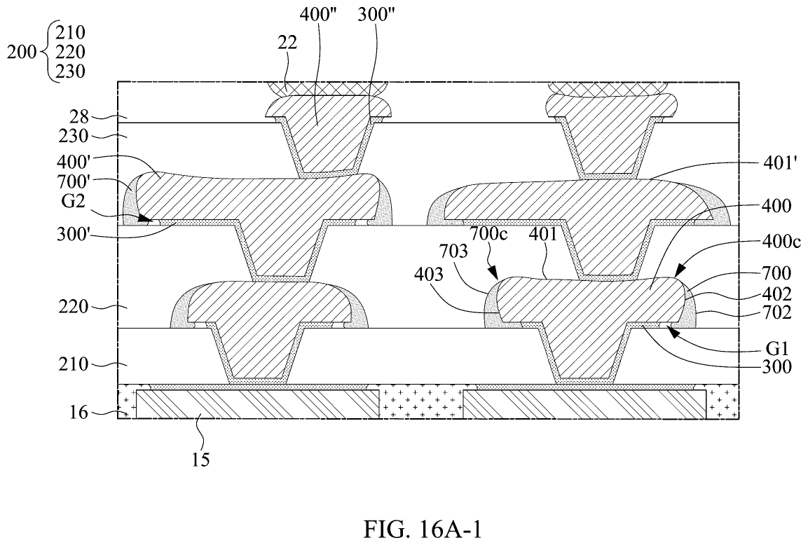

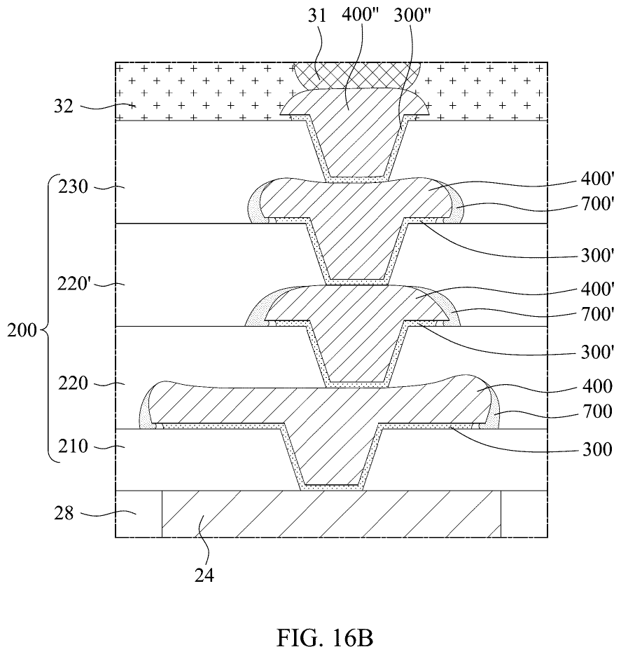

Referring to FIG. 16 and FIG. 16A, FIG. 16A shows a cross-sectional view of a portion 16A of the structure illustrated in FIG. 16 in accordance with some arrangements of the present disclosure. Operations similar to those illustrated in FIG. 6A to FIG. 6B may be performed to form the seed layer 300″ and the conductive layer 400″, so as to form an RDL 1000′. In some arrangements, operation similar to those illustrated in FIG. 7 may be performed to connect the substrate 10 to the substrate 20 through the RDL 1000′. In some arrangements, the RDL 1000′ includes a portion 15′ which may include a structure illustrated in FIG. 15, and the portion 16A of the RDL 1000′ may include a structure illustrated in FIG. 16A.

In some arrangements, referring to FIG. 16A-1, FIG. 16A-1 shows a cross-sectional view of a portion 16A of the structure illustrated in FIG. 16 in accordance with some arrangements of the present disclosure. In some arrangements, the barrier layer 700 contacts the seed layer 300. In some arrangements, the barrier layer 700′ contacts the seed layer 300′.

Referring to FIG. 16 and FIG. 8, operation similar to those illustrated in FIG. 8 may be performed to form a package structure similar to the package structure 1 illustrated in FIG. 8, and differences are that at least one of the RDL 1000 and the RDL 2000 may be replaced by the RDL 1000′. In some arrangements, the portion 7 of the structure illustrated in FIG. 8 may include a structure shown in FIG. 16. In some arrangements, the portion 8A illustrated in FIG. 8 may include a structure illustrated in FIG. 16B.

In some arrangements, referring to FIG. 16A and FIG. 16B, the upper surface (e.g., the surface 401) of the conductive layer 400 is exposed by the barrier layer 500. In some arrangements, the conductive layer 400′ is on and conformal with the upper surface (e.g., the surface 401) of the conductive layer 400. In some arrangements, the barrier layer 500′ is on the sidewalls of the conductive layer 400′. In some arrangements, the upper surface (e.g., the surface 401′) of the conductive layer 400′ is exposed by the barrier layer 500′. In some arrangements, the barrier layer 500 includes a tapered profile.

In addition, according to some arrangements of the present disclosure, the barrier layer 700 is formed by forming a barrier material layer 700A over the surface a dielectric layer 210 and the surfaces of trace portions of a conductive layer 400 followed by performing etching operations to form the barrier layer 700 including portions on sidewalls of the trace portions and separated from each other. The separated portions of the barrier layer 700 are formed by etching and thus can have relatively small sizes. Thus, the separated portions of the barrier layer 700 can be arranged between the trace portions having a relatively small pitch (e.g., a fine pitch). Therefore, metal atoms diffusion (e.g., copper diffusion) between the trace portions of the conductive layer 400 with a relatively small pitch can be prevented effectively, thus undesired short between the adjacent trace portions of the conductive layer 400 can be prevented, and a package structure with RDLs having a relatively small pitch can be achieved without undesirable short-circuit issues.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A method of forming a package structure, comprising:
providing a carrier;
forming a first conductive layer over the carrier;
forming a barrier material layer over a surface the first conductive layer;
melting the barrier material layer to allow the barrier material layer to flow from an upper side toward lateral sides of the first conductive layer to form a barrier layer over the first conductive layer and configured to reduce a lateral diffusion of the first conductive layer; and
depositing a second conductive layer over the first conductive layer.

2. The method as claimed in claim 1, further comprising depositing the barrier material layer on a top surface of the first conductive layer.

3. The method as claimed in claim 1, wherein melting the barrier material layer comprises performing a thermal treatment on the barrier material layer at a temperature higher than a melting point of the barrier material layer to allow the barrier material layer to keep flowing over sidewalls of the first conductive layer.

4. The method as claimed in claim 3, further comprising forming a dielectric layer over the carrier, wherein the first conductive layer is formed over the dielectric layer, and the performing the thermal treatment comprises heating the barrier material layer until the barrier material layer contacts the dielectric layer.

5. The method as claimed in claim 4, wherein performing the thermal treatment comprises heating the barrier material layer until the barrier material layer flows below the first conductive layer.

6. The method as claimed in claim 2, further comprising:
forming a seed material layer over the carrier, wherein the first conductive layer is formed on the seed material layer; and
partially removing seed material layer after depositing the barrier material layer.

7. The method as claims in claim 1, wherein melting the barrier material layer comprises performing a thermal treatment on the barrier material layer to form a convex curved surface of the barrier layer.

8. The method as claimed in claim 7, further comprising:
forming a dielectric layer over and exposing a portion of the convex curved surface of the barrier layer;
wherein the second conductive layer is formed on and conformal with the portion of the convex curved surface of the barrier layer.

9. The method as claimed in claim 1, further comprising forming a conductive pad over the second conductive layer and configured to electrically connect to an electronic component through a solder material.

10. The method as claimed in claim 5, further comprising forming a seed layer over the carrier, wherein the first conductive layer is formed on the seed layer, and performing the thermal treatment comprises heating the barrier material layer until the barrier material layer flows toward the seed layer.

11. The method as claimed in claim 10, wherein performing the thermal treatment comprises heating the barrier material layer until the barrier material layer contacts the seed layer.

12. A method of forming a package structure, comprising:
forming a first conductive layer over a carrier;
forming a barrier material layer over an upper surface and sidewalls of the first conductive layer; and
partially removing the barrier material layer to form a barrier layer on the sidewalls of the first conductive layer without contacting the upper surface of the first conductive layer.

13. The method as claimed in claim 12, further comprising forming a dielectric layer over the carrier, wherein partially removing the barrier material layer comprises:
performing a dry etch process to at least partially remove a first portion of the barrier material layer from the upper surface of the first conductive layer; and
performing a wet etch process to remove a second portion of the barrier material layer between trace portions of the first conductive layer to expose an upper surface of the dielectric layer.

14. The method as claimed in claim 13, wherein partially removing the barrier material layer comprises performing the dry etch process to partially remove the barrier material layer from lateral surfaces of the barrier material layer.

15. The method as claimed in claim 14, wherein partially removing the barrier material layer comprises performing the dry etch process in a direction from an upper surface of the barrier material layer toward the upper surface of the dielectric layer along the lateral surfaces of the barrier material layer.

16. The method as claimed in claim 13, further comprising forming a second conductive layer over the first conductive layer.

17. The method as claimed in claim 16, further comprising forming a conductive pad over the second conductive layer and configured to electrically connect to an electronic component through a solder material.

18. The method as claimed in claim 12, further comprising:
forming a seed material layer over the carrier, wherein the first conductive layer is formed on the seed material layer; and
partially removing the seed material layer before forming the barrier material layer.

19. The method as claimed in claim 18, further comprising depositing the barrier material layer to allow the barrier material layer to partially extend below the first conductive layer and be spaced apart from the seed material layer.

20. The method as claimed in claim 18, further comprising depositing the barrier material layer to allow the barrier material layer to partially extend below the first conductive layer and contacting the seed material layer.
